(19) United States
(12) Patent Application Publication
(10) Pub. No.: US 2002/0153573 A1
(43) Pub. Date: Oct. 24, 2002

(54) MIS field effect transistor and manufacturing method thereof

(76) Inventor: Tohru Mogami, Tokyo (JP)

Correspondence Address: YOUNG & THOMPSON, 745 SOUTH 23RD STREET 2ND FLOOR, ARLINGTON, VA, 22202

(21) Appl. No.: 09/507,049

(22) Filed: Feb. 22, 2000

(30) Foreign Application Priority Data
Feb. 19, 1999 (JP) 11-041727

(51) Int. Cl. H01L 29/76

(52) U.S. Cl. 257/369

(57) ABSTRACT

A gate electrode film of an MIS field effect transistor is formed to have a layered structure composed of conductor films, and so as to have a lower conductor film in contact with a gate insulation film approximately thin enough for at least allowing an upper layer conductor film to displace a potential of a substrate channel region and have a lower layer conductor film of one gate electrode film and a lower layer conductor film of the other gate electrode film of different electric polarity differ in film thickness from each other.

### BACKGROUND OF THE INVENTION

1. Field of the Invention

The present invention relates to a semiconductor device and a manufacturing method thereof and, more particularly, to an MIS field effect transistor in which depletion of a gate electrode is reduced and a manufacturing method thereof.

2. Description of the Related Art

Commonly used as a gate electrode in contact with a gate insulation film in a transistor is a polycrystal silicon film with impurities doped by ion implantation. In a transistor of this kind, in a region proximate to an area where a polycrystal silicon film comes into contact with a gate insulation film, lack of doping of sufficient impurities causes depletion, making an effective gate insulation film thickness larger. As a result, transistor performance will be degraded.

As polycrystal silicon films with impurities doped which are used as conventional gate electrodes, silicon films with a film thickness of 100˜150 nm or more are used. For doping impurities into a polycrystal silicon gate electrode, ion implantation is ordinarily employed. However, when a film thickness of the silicon film is small, implanted impurities will penetrate into a channel region of a silicon substrate to cause a phenomenon that a threshold voltage of a transistor indefinitely changes. It is therefore impossible to make a silicon film thinner than 100 nm.

Since such gate depletion depends on a relative ratio to a gate insulation film thickness, the effect of the depletion is extremely little when the film thickness of the insulation film is not less than 6˜8 nm. Accordingly, particularly when a gate length is not more than 0.25 μm, the gate depletion in question causes a conspicuous problem.

For coping with this problem, proposed is a transistor structure using a metallic film which causes no depletion as a gate electrode. A transistor using a metallic film as a gate electrode of this kind is disclosed, for example, in the article recited in “Technical Digest of 1997 International Electron Devices Conference” (Dec. 7, 1997), pp. 821- 824.

Recent CMOS devices, for suppressing a short channel effect in a transistor, use a gate electrode material having a work function suited for an electric polarity of each transistor, for example, using an n-type-doped polycrystal silicon film in an n-channel transistor and a p-type-doped polycrystal silicon film in a p-channel transistor. CMOS device of this kind is disclosed in the article recited in “Technical Digest of 1996 International Electron Devices Conference” (Dec. 8, 1996), pp. 455- 458.

Also, conventional MIS field effect transistors employ a structure in which a silicide film is formed on a gate electrode in order to make a gate electrode resistance smaller. As a device size is reduced, however, there is an increasing demand for further smaller gate electrode resistance and adoption of a metallic film whose resistance is smaller than that of a silicide film is under consideration.

In a case where a gate electrode is structured to have two layers of a metallic film and a polycrystal silicon film, however, heat treatment at a temperature of 700° C. or higher will cause silicidation reaction, which makes it impossible to maintain low resistance of the metallic film. Under these circumstances, proposed is a layered structure in which a barrier film 1203 such as a titanium nitride film is formed between a metallic film 1201 and a polycrystal silicon film 1202 as shown in FIG. 12.

As an example of a conventional transistor of this kind, there are transistors disclosed in Japanese Patent Laying-Open (Kokai) No. Heisei 8-222734 and Japanese Patent Laying-Open (Kokai) No. Heisei 9-246394.

The above-described conventional transistors using a metallic film as a gate electrode enable gate depletion to be prevented. In a CMOS structure, however, because of an n-channel MOS transistor and a p-channel MOS transistor existing together, it is difficult to set an optimum threshold voltage for both of the transistors.

On the other hand, in a conventional transistor employing a layered structure where a barrier film is formed between a metallic film and a polycrystal silicon film as a gate electrode, an optimum threshold voltage can be set for both of the transistors by changing an electric polarity of impurities doped into the silicon film. Because of doping of impurities by ion implantation, however, depletion of a gate electrode can not be sufficiently reduced.

### SUMMARY OF THE INVENTION

An object of the present invention is to provide an MIS field effect transistor which solves the above-described conventional shortcomings and reduces depletion of a gate electrode, as well as controlling a threshold voltage of a transistor with ease and a manufacturing method thereof.

According to one aspect of the invention, an MIS field effect transistor, comprises

a gate electrode film having a layered structure composed of conductor films,

the conductor film at a lowermost layer in contact with a gate insulation film is approximately thin enough to at least allow upper layer the conductor film to displace a potential of a substrate channel region, and the lowermost layer conductor film at one the gate electrode film and the lowermost layer conductor film at the other the gate electrode film whose electric polarity is different from that of one the gate electrode film are formed to have different film thicknesses from each other.

In the preferred construction, the lowermost layer conductor film is formed of the same material in both of the gate electrode films whose electric polarities are different from each other, and is a metallic film, a metallic nitride film, a metallic oxide film, a metallic silicide film or a semiconductor film with impurities doped.

In another preferred construction, upper layer the conductor film formed on the lowermost layer conductor film is formed of a material which is the same in both of the gate electrode films whose electric polarities are different from each other and is different from that of the lowermost layer conductor film, and is a metallic film, a metallic oxide film, a metallic nitride film or a metallic silicide film.

In another preferred construction, the lowermost layer conductor film is formed of the same material in both of the gate electrode films whose electric polarities are different from each other, and is a metallic film, a metallic nitride film, a metallic oxide film, a metallic silicide film or a semiconductor film with impurities doped, and

upper layer the conductor film formed on the lowermost layer conductor film is formed of a material which is the same in both of the gate electrode films whose electric polarities are different from each other and is different from that of the lowermost layer conductor film, and is a metallic film, a metallic oxide film, a metallic nitride film or a metallic silicide film.

In another preferred construction, between the lowermost layer conductor film and the upper layer conductor film, an interlayer conductor film made of a metallic nitride film or a metallic oxide film is formed, and the upper layer conductor film is formed of a metallic film or a metallic silicide film.

In another preferred construction, the lowermost layer conductor film is formed of the same material in both of the gate electrode films whose electric polarities are different from each other, and is a metallic film, a metallic nitride film, a metallic oxide film, a metallic silicide film or a semiconductor film with impurities doped, between the lowermost layer conductor film and the upper layer conductor film, an interlayer conductor film made of a metallic nitride film or a metallic oxide film is formed, and the upper layer conductor film is formed of a metallic film or a metallic silicide film.

In another preferred construction, upper layer the conductor film formed on the lowermost layer conductor film is formed of a material which is the same in both of the gate electrode films whose electric polarities are different from each other and is different from that of the lowermost layer conductor film, and is a metallic film, a metallic oxide film, a metallic nitride film or a metallic silicide film, between the lowermost layer conductor film and the upper layer conductor film, an interlayer conductor film made of a metallic nitride film or a metallic oxide film is formed, and the upper layer conductor film is formed of a metallic film or a metallic silicide film.

In another preferred construction, the lowermost layer conductor film is formed of the same material in both of the gate electrode films whose electric polarities are different from each other, and is a metallic film, a metallic nitride film, a metallic oxide film, a metallic silicide film or a semiconductor film with impurities doped, upper layer the conductor film formed on the lowermost layer conductor film is formed of a material which is the same in both of the gate electrode films whose electric polarities are different from each other and is different from that of the lowermost layer conductor film, and is a metallic film, a metallic oxide film, a metallic nitride film or a metallic silicide film, between the lowermost layer conductor film and the upper layer conductor film, an interlayer conductor film made of a metallic nitride film or a metallic oxide film is formed, and the upper layer conductor film is formed of a metallic film or a metallic silicide film.

According to another aspect of the invention, an MIS field effect transistor manufacturing method, comprising the steps of

forming a gate insulation film on a semiconductor substrate on which an element isolation region is formed,

on the gate insulation film, depositing a first conductor film which forms a gate electrode to have a thickness approximately enough for at least allowing an upper layer conductor film to be deposited at a later step to displace a potential of a substrate channel region,

appropriately removing the first conductor film which forms a gate electrode of one electric polarity in the MIS field effect transistor by etching,

on the first conductor film, depositing a second conductor film made of a material different from that of the first conductor film,

forming a gate electrode pattern by etching for a layered film composed of the first conductor film and the second conductor film, and

doping predetermined impurities into a source/drain region of each electric polarity in the semiconductor and activating the impurities by heat treatment.

In the preferred construction, the second conductor film is made of a material which is different from that of the first conductor film and is a metallic film, a metallic oxide film, a metallic nitride film or a metallic silicide film.

In another preferred construction, the first conductor film depositing step including depositing a material of the first conductor film to have a thickness set for the gate electrode of one electric polarity in the MIS field effect transistor, depositing a predetermined conductor film for use as an etching step, and depositing a material of the first conductor film to make a total film thickness of the first conductor film equal a thickness set for the gate electrode of the other electric polarity in the MIS field effect transistor, and at the first conductor film removing step, removing the first conductor film by etching on which the gate electrode of the other electric polarity is formed down to the position of the conductor film for use as an etching stop.

In another preferred construction, the MIS field effect transistor manufacturing method further comprise between the first conductor film removing step and the second conductor film depositing step, a step of depositing an interlayer formed of a metallic nitride film or a metallic oxide film.

Other objects, features and advantages of the present invention will become clear from the detailed description given herebelow.

### BRIEF DESCRIPTION OF THE DRAWINGS

The present invention will be understood more fully from the detailed description given herebelow and from the accompanying drawings of the preferred embodiment of the invention, which, however, should not be taken to be limitative to the invention, but are for explanation and understanding only.

In the drawings:

FIG. 1 is a sectional view showing a structure of an MISFET according to a first embodiment of the present invention;

FIG. 2 is a sectional view showing a structure of a specific example of the first embodiment;

FIG. 3A is a sectional view showing a manufacturing procedure of the first embodiment;

FIG. 3B is a sectional view showing the manufacturing procedure of the first embodiment;

FIG. 3C is a sectional view showing the manufacturing procedure of the first embodiment;

FIG. 4 is a sectional view showing a structure of an MISFET according to a second embodiment of the present invention;

FIG. 5 is a sectional view showing a structure of a specific example of the second embodiment;

FIG. 6A is a sectional view showing a manufacturing procedure of the second embodiment;

FIG. 6B is a sectional view showing the manufacturing procedure of the second embodiment;

FIG. 6C is a sectional view showing the manufacturing procedure of the second embodiment;

FIG. 7 is a sectional view showing a structure of an MISFET according to a third embodiment of the present invention;

FIG. 8A is a sectional view showing a manufacturing procedure of the third embodiment;

FIG. 8B is a sectional view showing the manufacturing procedure of the third embodiment;

FIG. 8C is a sectional view showing the manufacturing procedure of the third embodiment;

FIG. 9 is a sectional view showing a structure of an MISFET according to a fourth embodiment of the present invention;

FIG. 10A is a sectional view showing a manufacturing procedure of the fourth embodiment;

FIG. 10B is a sectional view showing the manufacturing procedure of the fourth embodiment;

FIG. 10C is a sectional view showing the manufacturing procedure of the fourth embodiment;

FIG. 11 is a diagram showing a relationship between a threshold value of an MISFET and a gate length of a transistor obtained in the first embodiment of the present invention;

FIG. 12 is a sectional view showing a structure of a conventional MISFET.

### DESCRIPTION OF THE PREFERRED EMBODIMENT

The preferred embodiment of the present invention will be discussed hereinafter in detail with reference to the accompanying drawings. In the following description, numerous specific details are set forth in order to provide a thorough understanding of the present invention. It will be obvious, however, to those skilled in the art that the present invention may be practiced without these specific details. In other instance, well-known structures are not shown in detail in order to unnecessary obscure the present invention.

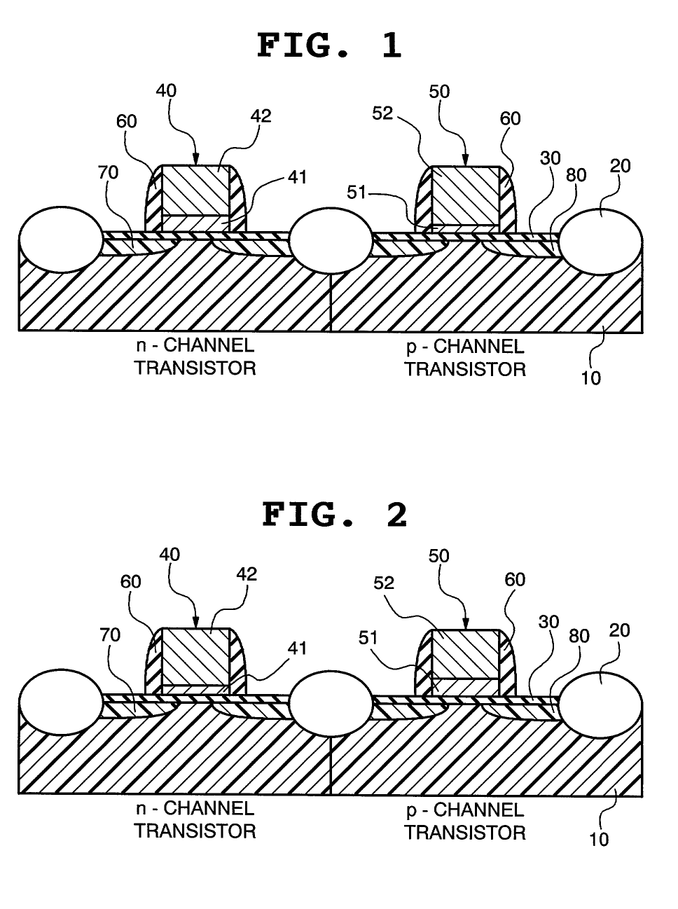

FIG. 1 is a sectional view showing a structure of an MISFET (Metal Insulator Semiconductor Field Effect Transistor) which is a semiconductor device according to the first embodiment of the present invention. With reference to FIG. 1, the MISFET of the present embodiment is structured to have a gate insulation film 30, which is divided by an element isolation oxide film 20, formed on a silicon substrate 10, and gate electrode films 40 and 50 with a gate electrode sidewall film 60 in their peripheries formed on the gate insulation film 30. In addition, at the gate insulation film 30 on the side of the silicon substrate 10, an n-type source/drain region 70 and a p-type source/drain region 80 are formed.

The gate electrode films 40 and 50 each have a layered structure composed of a lower conductor film 41, 51 whose thickness ranges from 20 to 60 nm and an upper conductor film 42, 52 whose thickness ranges from 50 to 800 nm. The lower conductor films 41 and 51 are made of silicon with impurities doped and the upper conductor films 42 and 52 are made of metallic nitride, metallic oxide, metal or metallic silicide.

In thus structured gate electrode films 40 and 50, when the lower conductor films 41 and 51 are made as thin as 20 to 60 nm, a threshold voltage of the transistor will not be determined solely by work functions of the lower conductor films 41 and 51 but be affected by work functions of the upper conductor films 42 and 52. In other words, a potential of a substrate channel region is displaced. This threshold voltage can be controlled by changing a film thickness of the lower conductor films 41 and 51, which therefore gives an advantage that a threshold voltage can be controlled independently of the quantity of substrate impurities of the transistor.

Used as the materials of the upper conductor films 42 and 52 in the present embodiment, for example, are a titanium nitride film, a tantalum nitride film, etc. for a metallic nitride film, a ruthenium oxide film, an iridium oxide film, etc. for a metallic oxide film, a tungsten film, a molybdenum film, etc. for a metallic film, and a titanium silicide film, a cobalt silicide film, etc. for a metallic silicide film. Moreover, it is clear that materials are not necessarily limited to those mentioned above and any material which can be used for the purpose of controlling a threshold voltage of an MISFET by a work function can be employed.

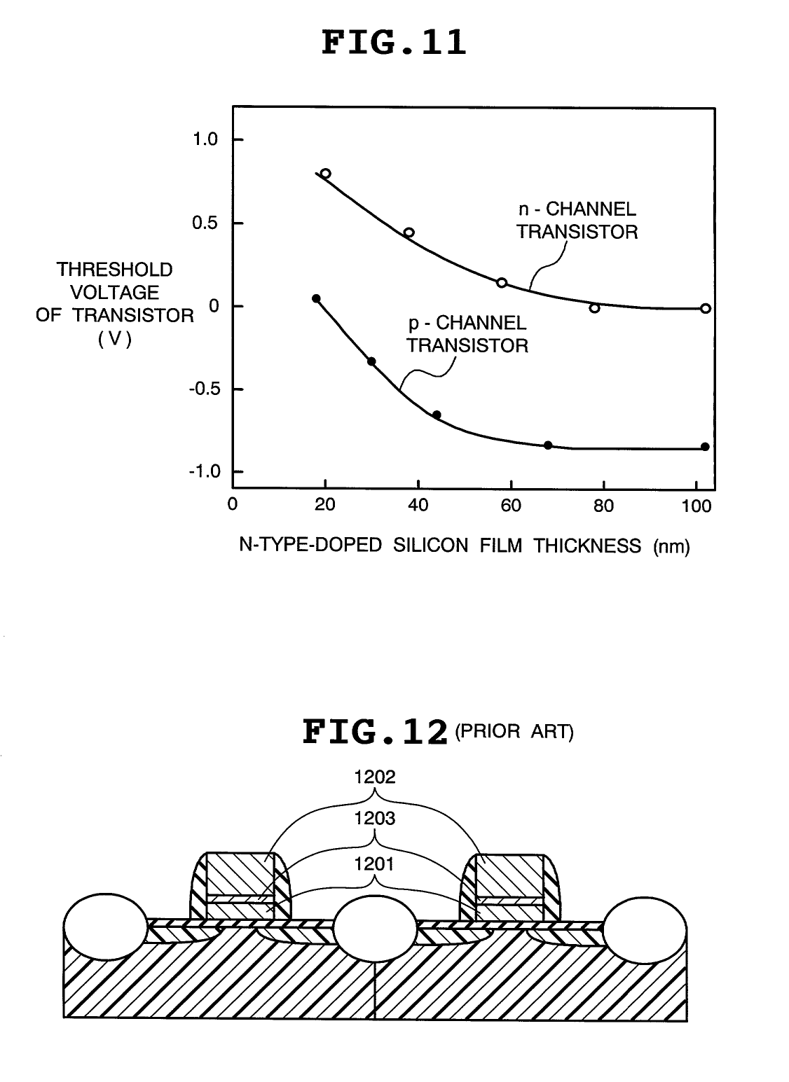

A relationship between a silicon film thickness and a transistor threshold voltage in the present embodiment is shown in FIG. 11. With reference to FIG. 11, as a result of making the silicon film thickness be not more than a fixed film thickness, the threshold voltage will be affected not only by work functions of the silicon films which are the lower conductor films 41 and 51 but also by work functions of metallic films which are the upper conductor films 42 and 52. It is therefore understood that by changing a film thickness of the silicon film, the threshold voltage can be controlled. In FIG. 11, when the film thickness of the lower conductor films 41 and 51 as polysilicon films is not more than about 60 nm, the tungsten films of the upper conductor films 42 and 52 affect the threshold voltage. It is also confirmed that the same effect is produced also when the upper conductor films 42 and 52 are metallic films or the like as will be described later.

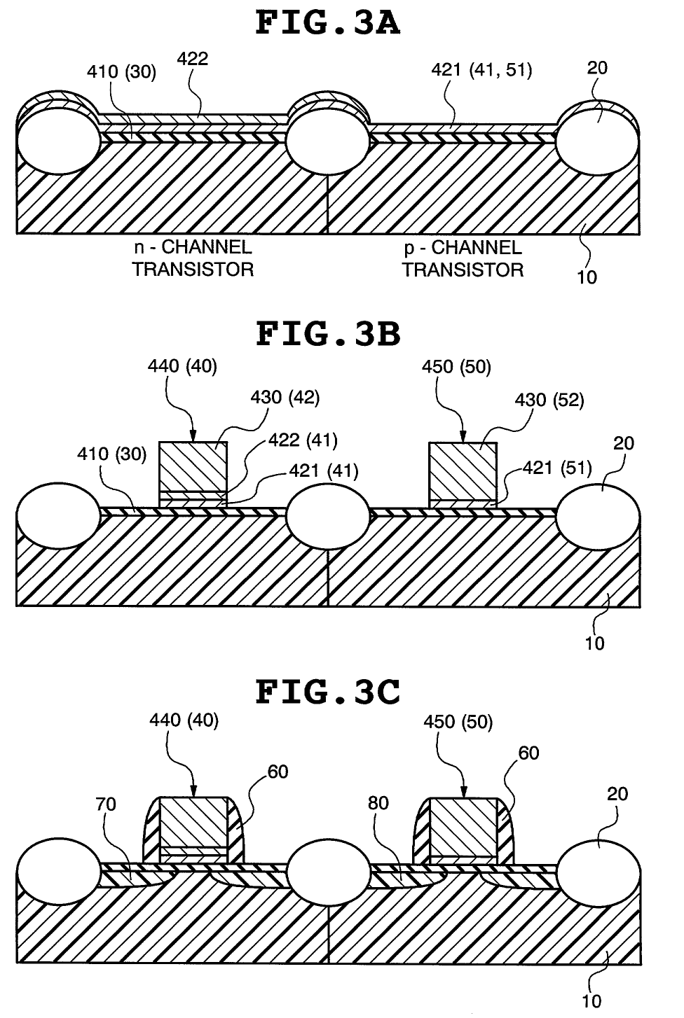

FIGS. 3A to 3C are views showing a manufacturing process of the MISFET according to the first embodiment shown in FIG. 1. With reference to FIGS. 3A to 3C, according to the MISFET manufacturing procedure of the present embodiment, first, form the gate insulation film 30 on the silicon substrate 10 on which the element isolation oxide film 20 is formed. Next, for forming the lower conductor films 41 and 51, deposit a silicon film with impurities doped to be 20-60 nm thick by the CVD method. Next, by appropriately removing the silicon film which forms one gate electrode film (the gate electrode film 50 of the p-channel transistor in the example shown) by etching, make the lower conductor films 41 and 51 in the two gate electrode films 40 and 50 have different film thicknesses (see FIG. 3A).

Next, for forming the upper conductor films 42 and 52, deposit a high melting point metallic film or the like to be 50 - 800 nm thick. Thereafter, form the gate electrodes by ordinary lithography step and etching step (see FIG. 3B).

Next, form an insulation film sidewall at each gate electrode and dope impurities into the source/drain regions to a high concentration. Then, activate the impurities by heat treatment to complete the MISFET (see FIG. 3C).

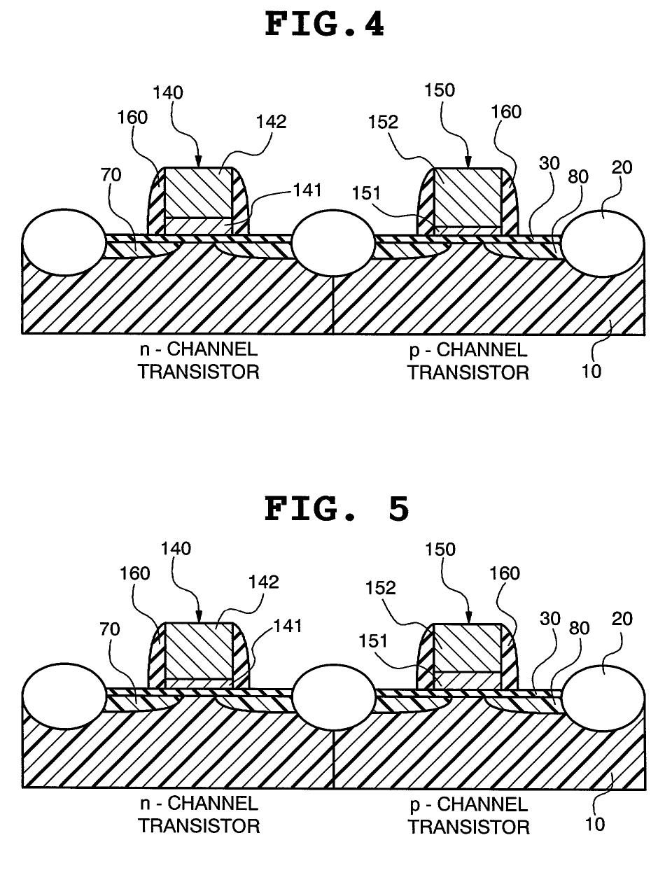

FIG. 4 is a sectional view showing a structure of an MISFET which is a semiconductor device according to the second embodiment of the present invention. With reference to FIG. 4, the MISFET of the present embodiment is structured to have a gate insulation film 30, which is divided by an element isolation oxide film 20, formed on a silicon substrate 10, and gate electrode films 140 and 150 with a gate electrode sidewall film 160 in their peripheries formed on the gate insulation film 30. On the gate insulation film 30 on the silicon substrate 10 side, an n-type source/drain region 70 and a p-type source/drain region 80 are formed.

The gate electrode films 140 and 150 each have a layered structure composed of a lower conductor film 141, 151 whose thickness ranges from 10 to 60 nm and an upper conductor film 142, 152 whose thickness ranges from 50 to 800 nm. The lower conductor films 141 and 151 and the upper conductor films 142 and 152 are formed of materials different from each other which are among metallic nitride, metallic oxide, metal and metallic silicide.

In thus structured gate electrode films 140 and 150, making the lower conductor films 141 and 151 be as thin as 20 to 60 nm results in having a threshold voltage of the transistor affected by the film thicknesses of the lower conductor films 141 and 151 and the work functions of the upper conductor films 142 and 152. In other words, a potential of the substrate channel region is displaced. It is therefore possible to control a threshold by appropriately selecting a combination of materials of these films.

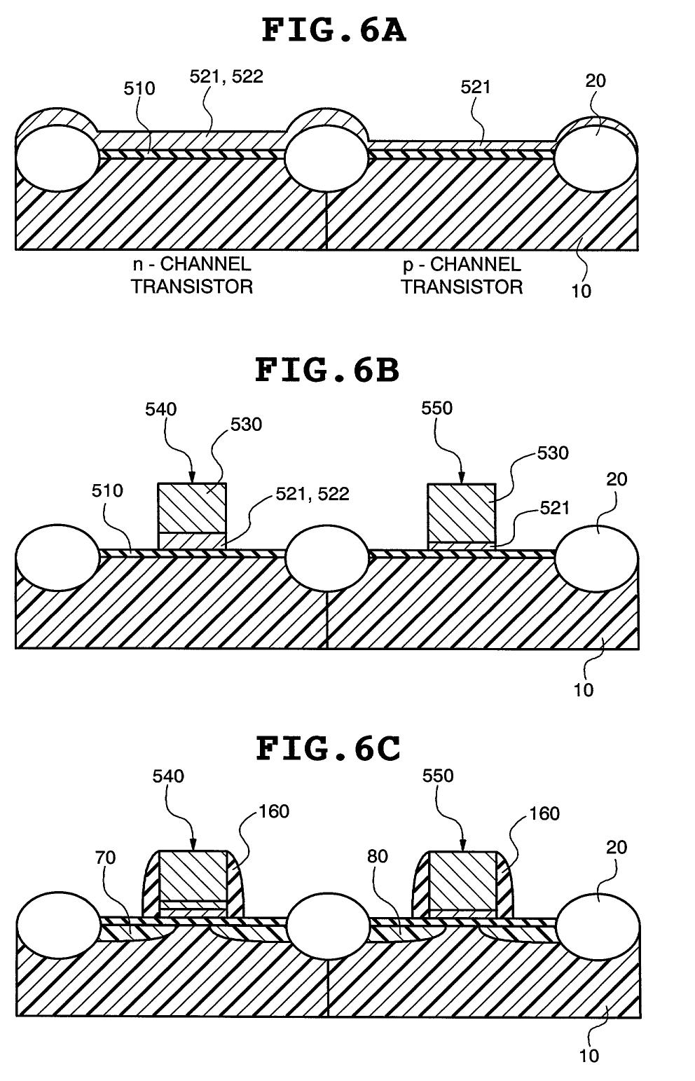

FIGS. 6A to 6C are views showing an MISFET manufacturing process according to the second embodiment shown in FIG. 4. With reference to FIGS. 6A to 6C, according to the MISFET manufacturing procedure of the present embodiment, first, form the gate insulation film 30 on the silicon substrate 10 on which the element isolation oxide film 20 is formed. Next, for forming the lower conductor films 141 and 151, deposit a metallic film, a metallic silicide film or the like to be 20-60 nm thick by sputtering etc. Next, by appropriately removing the metallic film or the like which forms one gate electrode film (the gate electrode film 150 of the p-channel transistor in the example shown) by etching, make the lower conductor films 141 and 151 in the two gate electrode films 140 and 150 have different film thicknesses (see FIG. 6A).

Next, for forming the upper conductor films 142 and 152, deposit a high melting point metallic film or the like to be 50-80 nm thick. Thereafter, form the gate electrodes by ordinary lithography step and etching step (see FIG. 6B).

Next, form an insulation film sidewall at each gate electrode and dope impurities into the source/drain regions to a high concentration. Then, activate the impurities by heat treatment to complete the MISFET (see FIG. 6C).

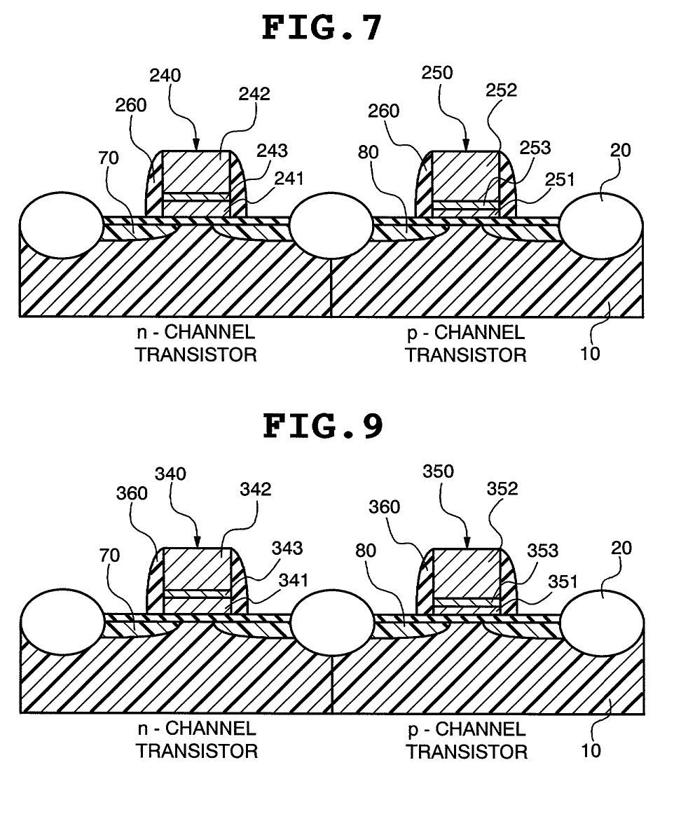

FIG. 7 is a sectional view showing a structure of an MISFET which is a semiconductor device according to the third embodiment of the present invention. With reference to FIG. 7, the MISFET of the present embodiment is structured to have a gate insulation film 30, which is divided by an element isolation oxide film 20, formed on a silicon substrate 10, and gate electrode films 240 and 250 with a gate electrode sidewall film 260 in their peripheries formed on the gate insulation film 30. On the gate insulation film 30 on the silicon substrate 10 side, an n-type source/drain region 70 and a p-type source/drain region 80 are formed.

The gate electrode films 240 and 250 each have a layered structure composed of a lower conductor film 241, 251 whose thickness ranges from 20 to 60 nm, an interlayer 243, 253 whose thickness ranges from 1 to 10 nm and an upper conductor film 242, 252 whose thickness ranges from 50 to 800 nm. The lower conductor films 241 and 251 are formed of silicon with impurities doped, the interlayers 243 and 253 are formed of metallic nitride and a nitride insulation film, and the upper conductor films 242 and 252 are formed of metal or metallic silicide.

In thus structured gate electrode films 240 and 250, providing a metallic nitride film or a metallic oxide film as the interlayers 243 and 253 respectively between the lower conductor films 241 and 251 and the upper conductor films 242 and 252 prevents, even when heat treatment is conducted at a high temperature at a transistor formation step, a silicon film as the lower conductor film and a metallic film or a metallic silicide film as the upper conductor film from reacting with each other.

In addition, making the interlayers 243 and 253 be as thin as 2 to 10 nm enables a threshold voltage of the transistor to be controlled by appropriately changing a film thickness of the silicon films which are the lower conductor films 241 and 251 similarly to the case where the interlayers 243 and 253 do not exist.

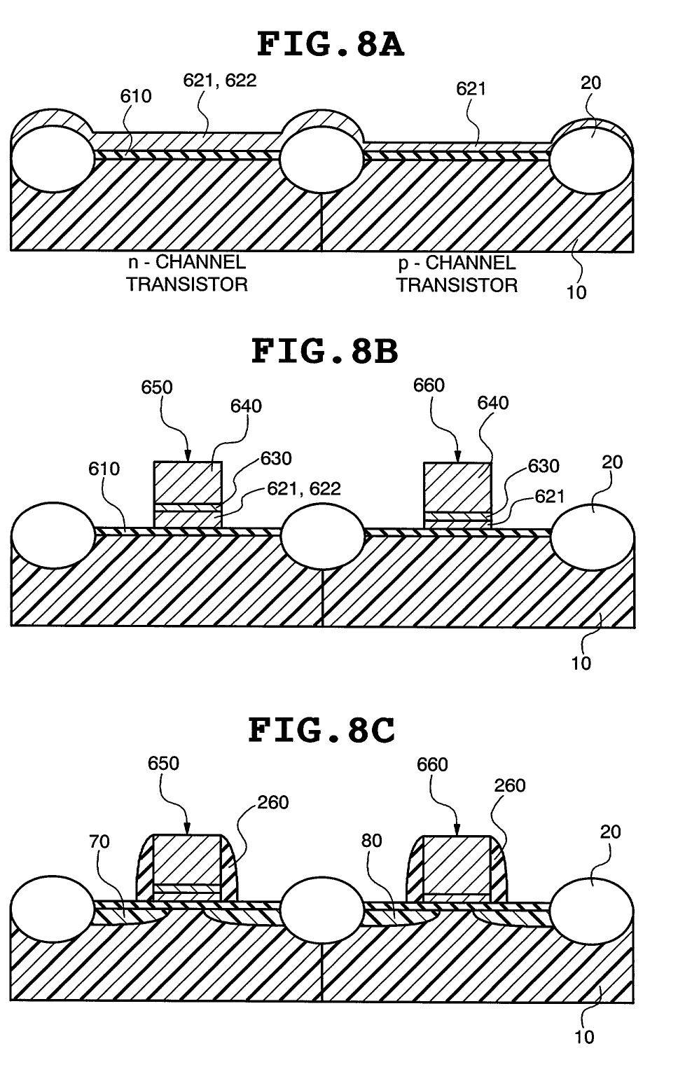

FIGS. 8A to 8C are views showing an MISFET manufacturing process according to the third embodiment shown in FIG. 7. With reference to FIGS. 8A to 8C, according to the MISFET manufacturing procedure of the present embodiment, first, form the gate insulation film 30 on the silicon substrate 10 on which the element isolation oxide film 20 is formed. Next, for forming the lower conductor films 241 and 251, deposit a silicon film with impurities doped to be 20-60 nm thick by the CVD method. Next, by appropriately removing the silicon film which forms one gate electrode film (the gate electrode film 250 of the p-channel transistor in the example shown) by etching, make the lower conductor films 241 and 251 in the two gate electrode films 240 and 250 have different film thicknesses (see FIG. 8A).

Next, for forming the interlayers 243 and 253, form a metallic nitride film or the like with a thickness of 1-10 nm by sputtering and furthermore, for forming the upper conductor films 242 and 252, deposit a metallic film, a metallic silicide film or the like to be 50 to 800 nm thick. Thereafter, form the gate electrodes by ordinary lithography step and etching step (see FIG. 8B).

Next, form an insulation film sidewall at each gate electrode and dope impurities into the source/drain regions to a high concentration. Then, activate the impurities by heat treatment at a temperature of 600 to 1000° C. to complete the MISFET (see FIG. 8C). In the present embodiment, providing the interlayers 243 and 253 made of a metallic nitride film or the like respectively between the lower conductor films 241 and 251 and the upper conductor films 242 and 252 enables reaction between the lower conductor films and the upper conductor films to be prevented during heat treatment at 600° C. or higher.

FIG. 9 is a sectional view showing a structure of an MISFET which is a semiconductor device according to the fourth embodiment of the present invention. With reference to FIG. 9, the MISFET of the present embodiment is structured to have a gate insulation film 30, which is divided by an element isolation oxide film 20, formed on a silicon substrate 10, and gate electrode films 340 and 350 with a gate electrode sidewall film 360 in their peripheries formed on the gate insulation film 30. On the gate insulation film 30 on the silicon substrate 10 side, an n-type source/drain region 70 and a p-type source/drain region 80 are formed.

The gate electrode films 340 and 350 each have a layered structure composed of a lower conductor film 341, 351 with a thickness of 20 to 60 nm, an interlayer 343, 353 with a thickness of 1 to 10 nm and an upper conductor film 342, 352 with a thickness of 50 to 800 nm. The lower conductor films 341 and 351 are formed of metallic nitride, metallic oxide, metal or metallic silicide, the interlayers 343 and 353 are formed of materials different from those of the lower conductor films 341 and 351 which are among metallic nitride and a nitride insulation film, and the upper conductor films 342 and 352 are formed of materials different from those of the interlayers 343 and 353 which are metal or metallic silicide.

In thus structured gate electrode films 340 and 350, making the lower conductor films 341 and 351 be as thin as 20 to 60 nm results in having a threshold voltage of the transistor affected by the film thickness of the lower conductor films 341 and 351 and the work functions of the upper conductor films 342 and 352, so that a threshold can be controlled by appropriately selecting a combination of materials of these films.

In addition, providing a metallic nitride film or a metallic oxide film as the interlayers 343 and 353 respectively between the lower conductor films 341 and 351 and the upper conductor films 342 and 352 enables reaction between the lower conductor films 341 and 351 and the upper conductor films 342 and 352 to be prevented during heat treatment at a high temperature in a transistor formation step.

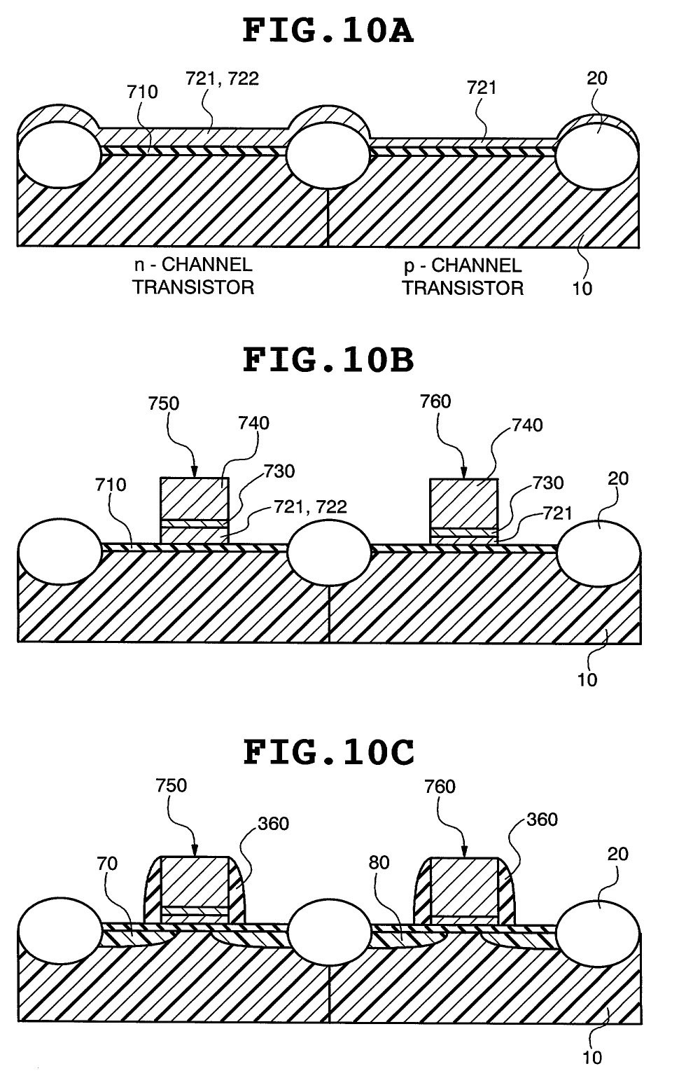

FIGS. 10A to 10C are views showing an MISFET manufacturing process according to the fourth embodiment shown in FIG. 9. With reference to FIGS. 8A to 8C, according to the MISFET manufacturing procedure of the present embodiment, first, form the gate insulation film 30 on the silicon substrate 10 on which the element isolation oxide film 20 is formed. Next, for forming the lower conductor films 341 and 351, deposit a metallic film or a metallic silicide film to be 20-60 nm thick by sputtering or the like. Next, by appropriately removing the metallic film or the like which forms one gate electrode film (the gate electrode film 350 of the p-channel transistor in the example shown) by etching, make the lower conductor films 341 and 351 in the two gate electrode films 340 and 350 have different film thicknesses (see FIG. 10A).

Next, for forming the interlayers 343 and 353, form a metallic nitride film or the like with a film thickness of 1 to 10 nm by sputtering and furthermore, for forming the upper conductor films 342 and 352, deposit a metallic film, a metallic silicide film or the like to be 50 to 800 nm thick. Thereafter, form the gate electrodes by ordinary lithography step and etching step (see FIG. 10B).

Next, form an insulation film sidewall at each gate electrode and dope impurities into the source/drain regions to a high concentration. Then, activate the impurities by heat treatment at a temperature of 600 to 1000° C. to complete the MISFET (see FIG. 10C). In the present embodiment, providing the interlayers 243 and 253 made of a metallic nitride film or the like respectively between the lower conductor films 241 and 251 and the upper conductor films 242 and 252 enables reaction between the lower conductor films and the upper conductor films to be prevented during heat treatment at 600° C. or higher.

First specific example is that corresponds to the first embodiment which has been described with reference to FIG. 1. In the MISFET of the present specific example, a gate length is 0.15 μm. In the gate electrode film 40 at the n-channel transistor region, the lower conductor film 41 is a polycrystal silicon film of 50 nm in thickness with impurities doped and the upper conductor film 42 is a tungsten silicide film of 80 nm in thickness. In the gate electrode film 50 at the p-channel transistor region, the lower conductor film 51 is a polycrystal silicon film of 30 nm in thickness with impurities doped and the upper conductor film 52 is a tungsten silicide film with a film thickness of 100 nm. The lower conductor films 41 and 51 are silicon films deposited by the CVD method and at the formation, have 5E20 cm⁻³ phosphorus doped as impurities in an electric furnace. The upper conductor films 42 and 52 are thin films deposited by sputtering.

On the gate electrodes, the insulation film sidewalls 60 are formed. In the n-channel transistor, arsenic as n-type impurities is implanted into the source/drain region 70 and in the p-channel transistor, boron as p-type impurities is implanted into the source/drain region 80.

In thus structured MISFET of the present specific example, a threshold voltage of the n-channel transistor in which the lower conductor film 41 has a film thickness of 50 nm was 0.3V. On the other hand, a threshold voltage of the p-channel transistor in which the lower conductor film 51 has a film thickness of 30 nm was −0.3V. The difference between the threshold voltages in question derives from a difference in effects of the tungsten silicide films as the upper conductor films 42 and 52 caused by a difference in film thickness between the lower conductor films 41 and 51.

In addition, a sheet resistance of the gate electrode is not more than 7 Ω/□ and a gate depletion rate was as good as not more than 10% because of doping of phosphorus into the lower conductor films 41 and 51 to a high concentration in an electronic furnace. Moreover, the gate structure was stable at a heat treatment temperature of 1000° C. Although in the present specific example, tungsten silicide films are used as the upper conductor films 42 and 52, materials are not necessarily limited thereto and the films may be formed of other silicide films such as a molybdenum silicide film, or metallic films.

Next, with reference to FIGS. 3A to 3C, description will be made of an MISFET manufacturing procedure according to the first specific example. With reference to FIGS. 3A to 3C, first, by the thermal oxidation method, form the gate oxide film 410 of 3 nm in thickness as the gate insulation film 30 on the silicon substrate 10 on which the element isolation oxide film 20 is formed by the LOCOS method. Next, for forming the lower conductor films 41 and 51, deposit the polycrystal silicon film 421 with phosphorus as impurities doped to be 30 nm thick by the low pressure CVD method. Here, phosphorus as impurities can be doped by, for example, mixing with silicon to deposit the film at the time of film formation or other method.

Next, on the phosphorus-doped polycrystal silicon film 421, form a 1-nm thick silicon oxide film and further deposit the polycrystal silicon film 422 with phosphorus as impurities doped to be 20 nm thick by the low pressure CVD method. Next, subject the polycrystal silicon films 421 and 422 in the p-channel transistor region to ordinary lithography step and etching step. At this time, etching is conducted down to a thickness of 30 nm with the silicon oxide film as an etching stop. In other words, at the p-channel transistor region, the polycrystal silicon film 422 is removed (see FIG. 3A).

Next, on the polycrystal silicon films 421 and 422, deposit the tungsten silicide film 430 to be 100 nm thick by sputtering for forming the upper conductor films 42 and 52. Next, by ordinary lithography step and etching step, form the gate electrodes 440 and 450 with a gate length of 0.15 μm (see FIG. 3B).

Next, form the insulation film sidewall 60 on each of the gate electrodes 440 and 450. Then, after doping arsenic into the source/drain region 70 of the n-channel transistor and boron into the source/drain region 80 of the p-channel transistor to a high concentration by ion implantation, activate the impurities by 1000 ° C. heat treatment to complete the MISFET (see FIG. 3C).

Second specific example is that corresponds to the first embodiment which has been described with reference to FIG. 1. Structure of the second specific example is shown in FIG. 2. In the MISFET of the present specific example, a gate length is 0.2 μm. In the gate electrode film 40 at the n-channel transistor region, the lower conductor film 41 is a polycrystal silicon film of 40 nm in thickness with impurities doped and the upper conductor film 42 is a titanium nitride film of 300 nm in thickness. In the gate electrode film 50 at the p-channel transistor region, the lower conductor film 51 is a polycrystal silicon film of 60 nm in thickness with impurities doped and the upper conductor film 52 is a titanium nitride film with a film thickness of 280 nm. The lower conductor films 41 and 51 are silicon films deposited by the CVD method and at the formation, have 3E20 cm⁻³ boron doped as impurities in an electric furnace. The upper conductor films 42 and 52 are thin films deposited by sputtering.

On the gate electrodes, the insulation film sidewalls 60 are formed. In the n-channel transistor, n-type impurities are implanted into the source/drain region 70 and in the p-channel transistor, p-type impurities are implanted into the source/drain region 80.

In thus structured MISFET of the present specific example, a threshold voltage of the n-channel transistor in which the lower conductor film 41 has a film thickness of 40 nm was 0.3V. On the other hand, a threshold voltage of the p-channel transistor in which the lower conductor film 51 has a film thickness of 60 nm was −0.3V. The difference between the threshold voltages in question derives from a difference in effects of the titanium nitride films as the upper conductor films 42 and 52 caused by a difference in film thickness between the lower conductor films 41 and 51.

In addition, a sheet resistance of the gate electrode is not more than 10 Ω/□ and a gate depletion rate was as good as not more than 10%. Moreover, the gate electrode structure was stable even at a heat treatment temperature as high as 1000° C. Although in the present specific example, titanium nitride films are used as the upper conductor films 42 and 52, materials are not necessarily limited thereto and the films may be formed of other metallic nitride films such as a molybdenum nitride film, or metallic oxide films.

Third specific example is that corresponds to the second embodiment which has been described with reference to FIG. 4. In the MISFET of the present specific example, a gate length is 0.12 μm. In the gate electrode film 140 at the n-channel transistor region, the lower conductor film 141 is a titanium nitride film whose thickness is 50 nm and the upper conductor film 142 is a tungsten film of 130 nm in thickness. In the gate electrode film 150 at the p-channel transistor region, the lower conductor film 151 is a titanium nitride film of 30 nm in thickness and the upper conductor film 152 is a tungsten film with a film thickness of 150 nm. The lower conductor films 141 and 151 and the upper conductor films 142 and 152 are all thin films deposited by the CVD method.

On the gate electrodes, the insulation film sidewalls 160 are formed. In the n-channel transistor, arsenic as n-type impurities is implanted into the source/drain region 70 and in the p-channel transistor, germanium and boron as p-type impurities are implanted into the source/drain region 80.

In thus structured MISFET of the present specific example, a threshold voltage of the n-channel transistor in which the lower conductor film 141 has a film thickness of 50 nm was 0.2V. On the other hand, a threshold voltage of the p-channel transistor in which the lower conductor film 151 has a film thickness of 30 nm was −0.2V. The difference between the threshold voltages in question derives from a difference in effects of the tungsten films as the upper conductor films 142 and 152 caused by a difference in film thickness between the lower conductor films 141 and 151.

In addition, a sheet resistance of the gate electrode is not more than 2 Ω/□ and a gate depletion rate was approximately 0% because the lower conductor films 141 and 151 are formed of titanium nitride films. Moreover, the gate electrode structure was stable even at a heat treatment temperature as high as 700° C. Although in the present specific example, titanium nitride is used for the lower conductor films 141 and 151, materials are not necessarily limited thereto and the films may be formed of other metallic nitride films such as tungsten nitride. Also, although tungsten is used for the upper conductor films 142 and 152, other metal such as molybdenum or a metallic silicide film may be used.

Next, with reference to FIGS. 6A to 6C, description will be made of an MISFET manufacturing procedure according to the third specific example. With reference to FIGS. 6A to 6C, first, by the thermal oxidation method, form the gate oxide film 510 of 2 nm in thickness as the gate insulation film 30 on the silicon substrate 10 on which the element isolation oxide film 20 is formed by trenching. Next, for forming the lower conductor films 141 and 151, deposit the titanium nitride film 521 to be 30 nm thick by the CVD method.

Next, on the titanium nitride film 521, form a 1-nm thick silicon oxide film and further, deposit the titanium nitride film 522 to be 20 nm thick by the CVD method. Next, subject the titanium nitride films 521 and 522 in the p-channel transistor region to ordinary lithography step and etching step. At this time, etching is conducted down to a thickness of 30 nm with the silicon oxide film as an etching stop. In other words, at the p-channel transistor region, the polycrystal silicon film 522 will be removed (see FIG. 6A).

Next, on the titanium nitride films 521 and 522, deposit the tungsten film 530 to be 150 nm thick by the CVD method for forming the upper conductor films 142 and 152. Next, by ordinary lithography step and etching step, form the gate electrodes 540 and 550 with a gate length of 0.1 μm (see FIG. 6B).

Next, form the insulation film sidewall 160 on each of the gate electrodes 440 and 450. Then, dope arsenic into the source/drain region 70 of the n-channel transistor to a high concentration by ion implantation. Also into the source/drain region 80 of the p-channel transistor, dope boron and germanium for amorphism to a high concentration by ion implantation. Thereafter, activate the impurities by 550° C. heat treatment to complete the MISFET (see FIG. 6C). Since the silicon substrate 10 is made amorphous by arsenic and germanium, heat treatment at 550° C. is conducted for full activation. Also, heat treatment at a temperature as low as 550° C. prevents reaction between titanium nitride films as the lower conductor films 141 and 151 and tungsten films as the upper conductor films 142 and 152.

Fourth specific example is that corresponds to the second embodiment which has been described with reference to FIG. 4. Structure of the fourth specific example is shown in FIG. 5. In the MISFET of the present specific example, a gate length is 0.1 μm. In the gate electrode film 140 at the n-channel transistor region, the lower conductor film 141 is a ruthenium oxide film whose thickness is 20 nm and the upper conductor film 142 is a ruthenium film of 150 nm in thickness. In the gate electrode film 150 at the p-channel transistor region, the lower conductor film 151 is a ruthenium oxide film of 50 nm in thickness and the upper conductor film 152 is a ruthenium film with a film thickness of 120 nm. The lower conductor films 141 and 151 and the upper conductor films 142 and 152 are all thin films deposited by the CVD method.

On the gate electrodes, the insulation film sidewalls 160 are formed. In the n-channel transistor, n-type impurities are implanted into the source/drain region 70 and in the p-channel transistor, germanium and p-type impurities are implanted into the source/drain region 80.

In thus structured MISFET of the present specific example, a threshold voltage of the n-channel transistor in which the lower conductor film 141 has a film thickness of 20 nm was 0.15V. On the other hand, a threshold voltage of the p-channel transistor in which the lower conductor film 151 has a film thickness of 50 nm was −0.15V. The difference between the threshold voltages in question derives from a difference in effects of the ruthenium films as the upper conductor films 142 and 152 caused by a difference in film thickness between the lower conductor films 141 and 151.

In addition, a sheet resistance of the gate electrode is not more than 2 Ω/□ and a gate depletion rate was 0% because the lower conductor films 141 and 151 are formed of ruthenium oxide films. Moreover, the gate electrode structure was stable even at a heat treatment temperature as high as 800 ° C. Although in the present specific example, ruthenium oxide is used for the lower conductor films 141 and 151, materials are not necessarily limited thereto and the films may be formed of other metallic oxide films such as iridium oxide. Also, although ruthenium is used for the upper conductor films 142 and 152, other metal such as iridium, or metallic silicide films may be used.

Fifth specific example is that corresponds to the third embodiment which has been described with reference to FIG. 7. In the MISFET of the present specific example, a gate length is 0.1 μm. In the gate electrode film 240 at the n-channel transistor region, the lower conductor film 241 is a 50-nm thick polycrystal silicon film with impurities doped, the interlayer 243 is a tungsten nitride film of 2 nm in thickness and the upper conductor film 242 is a tungsten film of 130 nm in thickness. In the gate electrode film 250 at the p-channel transistor region, the lower conductor film 251 is a polycrystal silicon film of 30 nm in thickness with impurities doped, the interlayer 253 is a tungsten nitride film of 2 nm in thickness and the upper conductor film 252 is a tungsten film with a film thickness of 150 nm. The lower conductor films 241 and 251 are silicon films deposited by the CVD method and have 5E20 cm⁻³ phosphorus doped as impurities in the electric furnace at the time of formation. The interlayers 243 and 253 are thin films deposited by sputtering, while the upper conductor films 242 and 252 are thin films deposited by the CVD method.

On the gate electrodes, the insulation film sidewalls 260 are formed. In the n-channel transistor, arsenic as n-type impurities is implanted into the source/drain region 70 and in the p-channel transistor, indium and boron as p-type impurities are implanted into the source/drain region 80.

In thus structured MISFET of the present specific example, a threshold voltage of the n-channel transistor in which the lower conductor film 241 has a film thickness of 50 nm was 0.2V. On the other hand, a threshold voltage of the p-channel transistor in which the lower conductor film 251 has a film thickness of 30 nm was −0.2V. The difference between the threshold voltages in question derives from a difference in effects of the tungsten films as the upper conductor films 242 and 252 caused by a difference in film thickness between the lower conductor films 241 and 251.

In addition, a sheet resistance of the gate electrode is not more than 5 Ω/□ and a gate depletion rate was not more than 10%. Moreover, the gate structure was stable at a heat treatment temperature of 1000° C. Although in the present specific example, a tungsten film is used for the upper conductor films 242 and 252, materials are not necessarily limited thereto and the films may be formed of other metallic film such as a molybdenum film, or a metallic silicide film. Also, although tungsten nitride is used for the interlayers 243 and 253, other metallic nitride film or a metallic oxide film may be used.

Next, with reference to FIGS. 8A to 8C, description will be made of an MISFET manufacturing procedure according to the fifth specific example. With reference to FIGS. 8A to 8C, first, by the thermal nitriding and oxidation method, form the gate oxide nitride film 610 of 2 nm in thickness as the gate insulation film 30 on the silicon substrate 10 on which the element isolation oxide film 20 is formed by trenching. Next, for forming the lower conductor films 241 and 251, deposit the polycrystal silicon film 621 with phosphorus as impurities doped to be 30 nm thick by the low pressure CVD method. Here, phosphorus as impurities can be doped by, for example, mixing with silicon to deposit the film at the time of formation of the film or other method.

Next, on the polycrystal silicon film 621 with phosphorus doped, form a 0.5-nm thick silicon oxide film and further, deposit the polycrystal silicon film 622 with phosphorus as impurities doped to be 20 nm thick by the low pressure CVD method. Next, subject the polycrystal silicon films 621 and 622 in the p-channel transistor region to ordinary lithography step and etching step. At this time, etching is conducted down to a thickness of 30 nm with the silicon oxide film as an etching stop. In other words, at the p-channel transistor region, the polycrystal silicon film 622 will be removed (see FIG. 8A).

Next, on the polycrystal silicon films 621 and 622, deposit the tungsten nitride film 630 to be 2 nm thick by sputtering for forming the interlayers 243 and 253. Furthermore, for forming the upper conductor films 242 and 252, deposit the tungsten film 640 to be 150 nm thick by the CVD method. Then, by ordinary lithography step and etching step, form the gate electrodes 650 and 660 with a gate length of 0.1 μm (see FIG. 8B).

Next, form the insulation film sidewall 260 on each of the gate electrodes 650 and 660. Then, dope arsenic into the source/drain region 70 of the n-channel transistor to a high concentration by ion implantation. Also into the source/drain region 80 in the p-channel transistor, dope boron and indium for amorphism to a high concentration by ion implantation. Thereafter, activate the impurities by 600° C. heat treatment to complete the MISFET (see FIG. 8C). Since the silicon substrate 10 is made amorphous by arsenic and indium, heat treatment is conducted at 600° C. for full activation. Provision of the interlayers 243 and 253 prevents reaction between polycrystal silicon films as the lower conductor films 241 and 251 and tungsten films as the upper conductor films 242 and 252 at the time of heat treatment.

Sixth specific example is that corresponds to the fourth embodiment which has been described with reference to FIG. 9. In the MISFET of the present specific example, a gate length is 0.08 μm. In the gate electrode film 340 at the n-channel transistor region, the lower conductor film 341 is a tungsten film with a thickness of 50 nm, the interlayer 343 is a titanium nitride film of 2 nm in thickness and the upper conductor film 342 is a platinum film of 120 nm in thickness. In the gate electrode film 350 at the p-channel transistor region, the lower conductor film 351 is a tungsten film of 20 nm in thickness, the interlayer 353 is a titanium nitride film of 2 nm in thickness and the upper conductor film 352 is a platinum film with a film thickness of 150 nm. The lower conductor films 341 and 351 and the upper conductor films 342 and 352 are all thin films deposited by the CVD method. The interlayers 343 and 353 are thin films deposited by sputtering.

On the gate electrodes, the insulation film sidewalls 360 are formed. In the n-channel transistor, arsenic as n-type impurities is implanted into the source/drain region 70 and in the p-channel transistor, indium and boron as p-type impurities are implanted into the source/drain region 80.

In thus structured MISFET of the present specific example, a threshold voltage of the n-channel transistor in which the lower conductor film 341 has a film thickness of 50 nm was 0.1V. On the other hand, a threshold voltage of the p-channel transistor in which the lower conductor film 351 has a film thickness of 20 nm was −0.1V. The difference between the threshold voltages in question derives from a difference in effects of the platinum films as the upper conductor films 342 and 352 caused by a difference in film thickness between the lower conductor films 341 and 351.

In addition, a sheet resistance of the gate electrode is not more than 1 Ω/□ and a gate depletion rate was 0% because the lower conductor films 341 and 351 are formed of tungsten films. Moreover, the gate electrode structure was stable even when a heat treatment temperature is increased up to 800° C. because of the provision of the titanium nitride films as the interlayers 343 and 353. Although in the present specific example, a tungsten film is used for the lower conductor films 341 and 351, materials are not necessarily limited thereto and the films may be formed of other metallic film such as molybdenum, or a metallic silicide film. Also, although titanium nitride is used for the interlayers 343 and 353, a metallic nitride film such as tungsten nitride, or a metallic oxide film may be used. Moreover, although platinum is used for the upper conductor films 342 and 352, the films may be formed of other metallic film such as iridium, or a metallic silicide film.

Next, with reference to FIGS. 10A to 10C, description will be made of an MISFET manufacturing procedure according to the sixth specific example. With reference to FIGS. 10A to 10C, first, form a layered film composed of a gate oxide nitride film 711 of 0.5 nm in thickness and a tantalum pentoxide film 712 of 2 nm in thickness as the gate insulation film 30 on the silicon substrate 10 on which the element isolation oxide film 20 is formed by trenching. Next, for forming the lower conductor films 341 and 351, deposit a tungsten film 721 to be 20 nm thick by the CVD method.

Next, on the tungsten film 721, form a 0.5-nm tungsten nitride film and further, deposit a tungsten film 722 to be 30 nm. Next, subject the tungsten films 721 and 722 in the p-channel transistor region to ordinary lithography step and etching step. At this time, etching is conducted down to a thickness of 20 nm with the tungsten nitride film as an etching stop. In other words, at the p-channel transistor region, the tungsten film 722 will be removed (see FIG. 10A).

Next, on the tungsten films 721 and 722, deposit a titanium nitride film 730 to be 2 nm thick by sputtering for forming the interlayers 343 and 353. Furthermore, for forming the upper conductor films 342 and 352, deposit a platinum film 740 to be 120 nm thick by the CVD method. Then, by ordinary lithography step and etching step, form gate electrodes 750 and 760 with a gate length of 0.08 μm (see FIG. 10B).

Next, form the insulation film sidewall 360 on each of the gate electrodes 750 and 760. Then, dope arsenic into the source/drain region 70 of the n-channel transistor to a high concentration by ion implantation. Also, dope boron and indium for amorphism to a high concentration into the source/drain region 80 of the p-channel transistor by ion implantation. Thereafter, activate the impurities by 650° C. heat treatment to complete the MISFET (see FIG. 10C). Since the silicon substrate 10 is made amorphous by arsenic and indium, heat treatment is conducted at 650° C. for full activation. Provision of the interlayers 343 and 353 prevents reaction between the tungsten films as the lower conductor films 341 and 351 and the platinum films as the upper conductor films 342 and 352 at the time of heat treatment.

As described in the foregoing, the MIS field effect transistor and the manufacturing method thereof of the present invention suppress depletion of a gate electrode film, so that when a gate electrode film has a layered structure, a lower conductor film can be made sufficiently thin. This makes it possible to exercise the effects of a work function of an upper conductor film on a threshold voltage of a transistor, whereby by changing film thicknesses of the lower conductor films in an n-channel transistor and a p-channel transistor, a threshold voltage of the transistor can be controlled. It is accordingly possible to control a threshold voltage independently of the quantity of substrate impurities in the transistor, thereby facilitating appropriate setting of a threshold voltage.

Another advantage is that controlling of a threshold voltage of a transistor according to a film thickness of a lower conductor film of a gate electrode film enables both a resistance and depletion at an upper conductor film to be reduced.

Moreover, conducting heat treatment for activating impurities after a source/drain region is made amorphous allows heat treatment to be executed at a low temperature. As a result, reaction between layers of a gate electrode having a layered structure at the time of heat treatment can be prevented, which is an effective phenomenon when a metallic film is used for a gate electrode.

Although the invention has been illustrated and described with respect to exemplary embodiment thereof, it should be understood by those skilled in the art that the foregoing and various other changes, omissions and additions may be made therein and thereto, without departing from the spirit and scope of the present invention. Therefore, the present invention should not be understood as limited to the specific embodiment set out above but to include all possible embodiments which can be embodies within a scope encompassed and equivalents thereof with respect to the feature set out in the appended claims.

What is claimed is:

1. An MIS field effect transistor, comprising
a gate electrode film having a layered structure composed of conductor films,
said conductor film at a lowermost layer in contact with a gate insulation film is approximately thin enough to at least allow upper layer said conductor film to displace a potential of a substrate channel region, and
said lowermost layer conductor film at one said gate electrode film and said lowermost layer conductor film at the other said gate electrode film whose electric polarity is different from that of one said gate electrode film are formed to have different film thicknesses from each other.

2. The MIS field effect transistor as set forth in claim 1, wherein
said lowermost layer conductor film
is formed of the same material in both of said gate electrode films whose electric polarities are different from each other, and
is a metallic film, a metallic nitride film, a metallic oxide film, a metallic silicide film or a semiconductor film with impurities doped.

3. The MIS field effect transistor as set forth in claim 1, wherein
upper layer said conductor film formed on said lowermost layer conductor film
is formed of a material which is the same in both of said gate electrode films whose electric polarities are different from each other and is different from that of said lowermost layer conductor film, and
is a metallic film, a metallic oxide film, a metallic nitride film or a metallic silicide film.

4. The MIS field effect transistor as set forth in claim 1, wherein
said lowermost layer conductor film
is formed of the same material in both of said gate electrode films whose electric polarities are different from each other, and
is a metallic film, a metallic nitride film, a metallic oxide film, a metallic silicide film or a semiconductor film with impurities doped, and
upper layer said conductor film formed on said lowermost layer conductor film
is formed of a material which is the same in both of said gate electrode films whose electric polarities are different from each other and is different from that of said lowermost layer conductor film, and
is a metallic film, a metallic oxide film, a metallic nitride film or a metallic silicide film.

5. The MIS field effect transistor as set forth in claim 1, wherein
between said lowermost layer conductor film and said upper layer conductor film, an interlayer conductor film made of a metallic nitride film or a metallic oxide film is formed, and
said upper layer conductor film is formed of a metallic film or a metallic silicide film.

6. The MIS field effect transistor as set forth in claim 1, wherein
said lowermost layer conductor film
is formed of the same material in both of said gate electrode films whose electric polarities are different from each other, and
is a metallic film, a metallic nitride film, a metallic oxide film, a metallic silicide film or a semiconductor film with impurities doped,
between said lowermost layer conductor film and said upper layer conductor film, an interlayer conductor film made of a metallic nitride film or a metallic oxide film is formed, and
said upper layer conductor film is formed of a metallic film or a metallic silicide film.

7. The MIS field effect transistor as set forth in claim 1, wherein
upper layer said conductor film formed on said lowermost layer conductor film
is formed of a material which is the same in both of said gate electrode films whose electric polarities are different from each other and is different from that of said lowermost layer conductor film, and
is a metallic film, a metallic oxide film, a metallic nitride film or a metallic silicide film,
between said lowermost layer conductor film and said upper layer conductor film, an interlayer conductor film made of a metallic nitride film or a metallic oxide film is formed, and
said upper layer conductor film is formed of a metallic film or a metallic silicide film.

8. The MIS field effect transistor as set forth in claim 1, wherein
said lowermost layer conductor film
is formed of the same material in both of said gate electrode films whose electric polarities are different from each other, and
is a metallic film, a metallic nitride film, a metallic oxide film, a metallic silicide film or a semiconductor film with impurities doped,
upper layer said conductor film formed on said lowermost layer conductor film
is formed of a material which is the same in both of said gate electrode films whose electric polarities are different from each other and is different from that of said lowermost layer conductor film, and
is a metallic film, a metallic oxide film, a metallic nitride film or a metallic silicide film,
between said lowermost layer conductor film and said upper layer conductor film, an interlayer conductor film made of a metallic nitride film or a metallic oxide film is formed, and
said upper layer conductor film is formed of a metallic film or a metallic silicide film.

9. An MIS field effect transistor manufacturing method, comprising the steps of:
forming a gate insulation film on a semiconductor substrate on which an element isolation region is formed;
on said gate insulation film, depositing a first conductor film which forms a gate electrode to have a thickness approximately enough for at least allowing an upper layer conductor film to be deposited at a later step to displace a potential of a substrate channel region;
appropriately removing said first conductor film which forms a gate electrode of one electric polarity in said MIS field effect transistor by etching;
on said first conductor film, depositing a second conductor film made of a material different from that of said first conductor film;
forming a gate electrode pattern by etching for a layered film composed of said first conductor film and said second conductor film; and
doping predetermined impurities into a source/drain region of each electric polarity in said semiconductor and activating the impurities by heat treatment.

10. The MIS field effect transistor manufacturing method as set forth in claim 9, wherein
said second conductor film is made of a material which is different from that of said first conductor film and is a metallic film, a metallic oxide film, a metallic nitride film or a metallic silicide film.

11. The MIS field effect transistor manufacturing method as set forth in claim 9, wherein
said first conductor film depositing step including
depositing a material of said first conductor film to have a thickness set for the gate electrode of one electric polarity in said MIS field effect transistor,
depositing a predetermined conductor film for use as an etching step, and
depositing a material of said first conductor film to make a total film thickness of said first conductor film equal a thickness set for the gate electrode of the other electric polarity in said MIS field effect transistor, and
at said first conductor film removing step,
removing said first conductor film by etching on which said gate electrode of the other electric polarity is formed down to the position of said conductor film for use as an etching stop.

12. The MIS field effect transistor manufacturing method as set forth inclaim 9, further comprising,
between said first conductor film removing step and said second conductor film depositing step, a step of depositing an interlayer formed of a metallic nitride film or a metallic oxide film.
